(19) United States
(12) Patent Application Publication
(10) Pub. No.: US 2020/0020688 A1
(43) Pub. Date: Jan. 16, 2020

(54) INTEGRATED CIRCUITS EMPLOYING VARIED GATE TOPOGRAPHY BETWEEN AN ACTIVE GATE REGION(S) AND A FIELD GATE REGION(S) IN A GATE(S) FOR REDUCED GATE LAYOUT PARASITIC CAPACITANCE, AND RELATED METHODS

(71) Applicant: QUALCOMM Incorporated, San Diego, CA (US)

(72) Inventors: Mustafa Badaroglu, Kessel-Lo (Leuven) (BE); Kern Rim, San Diego, CA (US)

(21) Appl. No.: 16/034,703

(22) Filed: Jul. 13, 2018

(51) Int. Cl. H01L 27/088; H01L 29/08; H01L 29/10; H01L 29/423; H01L 29/40; H01L 21/8234; H01L 29/66; H01L 21/027; H01L 21/3213; H01L 27/02

(52) U.S. Cl. CPC H01L 27/0886; H01L 29/0847; H01L 29/1037; H01L 29/42376; H01L 29/402; H01L 29/42392; H01L 21/823807; H01L 21/823437; H01L 29/66545; H01L 21/0273; H01L 21/823431; H01L 21/32139; H01L 27/0207; H01L 21/823412

(57) ABSTRACT

Integrated circuits employing varied gate topography between an active gate region(s) and a field gate region(s) in a gate(s) for reduced gate layout parasitic capacitance, and related methods, are disclosed. In exemplary aspects, the gate topography (e.g., height) of a gate in a circuit cell used to form gates for devices formed therein to form an integrated circuit is varied between an active gate and a field gate(s) of the gate. In this manner, the overall volume of material in the gate can be reduced due to the reduction in volume of the field gate(s) to reduce gate layout parasitic capacitance. Reducing gate layout parasitic capacitance in a circuit cell can reduce the overall parasitic capacitance of an integrated circuit formed from the circuit cell to achieve the desired integrated circuit delay performance.

### BACKGROUND

### I. Field of the Disclosure

The technology of the disclosure relates generally to integrated circuits, such as planar transistors, Fin Field-Effect Transistors (FETs) (FinFETs), and gate-all-around (GAA) transistors, formed from a circuit cell, such as a complementary metal-oxide semiconductor (CMOS) standard cell, in integrated circuits (ICs).

### II. Background

Transistors are essential components in modern electronic devices, and large numbers of transistors are employed in integrated circuits (ICs) therein. For example, components such as central processing units (CPUs) and memory systems each employ a large quantity of transistors for logic circuits and memory devices. For example, FIG. 1 illustrates a conventional complementary metal-oxide semiconductor (CMOS) Fin Field-Effect Transistor (FET) 100 (“FinFET 100”) as an example of a transistor. A FinFET includes a gate material wrapped around at least a portion of a channel structure to provide better gate control over an active channel therein. Better gate control provides reduced current leakage and increased threshold voltage as compared to a planar transistor of a similar footprint.

In this regard, FIG. 1 illustrates the FinFET 100 as including a substrate 102 and Fins 104A, 104B made of a semiconductor material and disposed above the substrate 102 to form a semiconductor material structure 106 across the FinFET 100. The FinFET 100 further includes source/drain elements 108A, 108B disposed above the Fins 104A, 104B, respectively, to provide a source and drain for the FinFET 100. The FinFET 100 further includes a source/drain contact 112A disposed on the substrate 102 to provide a contact to the source/drain elements 108A, 108B. The FinFET 100 further includes a source/drain contact 112B on a side 110 of the FinFET 100 to provide a contact to drain/source regions (not shown). The FinFET 100 further includes spacer layers 114A and 114B (e.g., a Nitride-based low-k material or air) disposed on the substrate 102 to isolate the source/drain contacts 112A, 112B, respectively, from a “wrap-around” gate 116 disposed on the substrate 102 and over the Fins 104A, 104B between the spacer layers 114A, 114B. The FinFET 100 further includes a gate contact 118 disposed on the gate 116 to provide a contact to the gate 116. The FinFET 100 further includes an interlayer dielectric (ILD) 120 to isolate active components of the FinFET 100 from other devices disposed near the FinFET 100. Thus, FinFETs such as the FinFET 100 in FIG. 1 are capable of delivering high current through a small silicon footprint. Improved electrostatic control and a taller Fin height enable high “ON” current for FinFETs.

For example, FIG. 2 below illustrates a top view of a layout 200 of a conventional standard cell 202 that can be used to form FinFETs, such as the FinFET 100 in FIG. 1, to illustrate the parasitic capacitances between the gate and source/drain of the FinFETs. The standard cell 202 includes gates 204(1)-204(4) disposed in a first direction 206 on a Y-axis with a defined gate pitch G_{P}. The standard cell 202 includes a first voltage rail 208 configured to be coupled to a supply voltage. The first voltage rail 208 is disposed in a second direction 210 in an X-axis substantially orthogonal to the first direction 206 in a first metal layer 212 (e.g., a metal zero (MO) metal layer). Additionally, the standard cell 202 includes a second voltage rail 214 disposed in the second direction 210 in the first metal layer 212. The standard cell 202 also includes diffusion regions 216P, 216N of P-type doped and N-type doped semiconductor materials, respectively, for forming active devices that include semiconducting materials, such as transistors. The standard cell 202 also includes Fins 218(1)-218(4) for forming semiconductor channels of FinFETs disposed in the second direction 210 between the first and second voltage rails 208, 214. In this example, a FinFET formed in the diffusion region 216P will include two Fins 218(1), 218(2) to form its channel, and a FinFET formed in the diffusion region 216N will include two Fins 218(3), 218(4) to form its semiconductor channel. Trench contacts 220(1)-220(3) are also formed in the first direction 206 to provide contacts to source/drain regions S(1)-S(4), D(1)-D(4) of Fins 218(1), 218(2) formed in the standard cell 202. Trench contact 220(1) has been cut. A metal line 222(1) can be formed in the first metal layer (MO) 212 to provide an interconnection to the trench contact 220(1) to provide interconnections to the source or drain region S(1), D(1). Vias (V1) 224(1), 224(2) can be formed over portions of the gates 204(1)-204(4) to form metal contacts to the gates 204(1)-204(4).

One substantial factor that contributes to the performance of a FinFET, such as the FinFET 100 in FIG. 1, is the contact resistance between the source and drain contacts and their respective source and drain. In digital circuits in particular, as a particular stage switches, a high junction contact resistance of the source causes a large current (I) resistance (R) (IR) drop, thereby reducing gate overdrive, which in turn reduces switching speed (i.e., increases delay). Additionally, parasitic capacitance of the FinFET reduces switching speed of the FinFET. For example, the parasitic capacitance between the gate and the source/drain and source/drain contacts adds to coupling capacitance between the gate contributing to the gate capacitance.

In this regard, with reference back to FIG. 2, parasitic capacitances between the active portions of the gate 204(3) and the source/drain regions S(1)-S(4), D(1)-D(4) are shown as parasitic capacitances C₁-C₄, and which are referred to as device capacitances. Parasitic capacitances between the field portion (i.e., non-active portion) of the gate 204(3) and trench contacts 220(2)-220(3) are shown as parasitic capacitances C₅-C₆, and are referred to as layout capacitances. The parasitic capacitance of a FinFET also contributes to a Miller capacitance effect of the FinFET. The Miller capacitance effect accounts for a significant portion of effective gate capacitance due to amplification of the effect of the gate-to-drain capacitance. An increase in Miller capacitance can have a significant impact on switching delay of the FinFET.

The trend to scale down the size of a standard cell, such as the standard cell 202 in FIG. 2, increases parasitic capacitance, because the spacing between the gate and the metal lines in the standard cell as well as the number of active fins are reduced as the standard cell is scaled down. This increases the portion of layout capacitance in the total capacitance, and thus also increases the Miller capacitance portion. Also, Fins in a FinFET may be fabricated taller in a standard cell to offset a reduction in the number of Fins included in the FinFET as the node size is scaled down while maintaining drive strength. However, increasing the Fin height also increases the gate height to wrap around the Fin, and thus may also increase the height of the source and drain contacts, thereby increasing the capacitance over not increasing Fin height. Scaling down the channel length of the FinFET together with the scaling of the gate pitch also affects the width of gate spacers, dielectric layers, and work function metal layers, thus reducing the available space for the actual gate fill material, because the gate spacer, dielectric layer, and work function metal layers must still be provided even if the gate width is reduced. For example, scaling down gate length may result in a three (3) times factor reduction in the volume of gate fill material. Thus, performance of the FinFET will degrade because of the decrease in gate control of the electric field in the channel.

### SUMMARY OF THE DISCLOSURE

Aspects disclosed herein include integrated circuits employing varied gate topography between an active gate region(s) and a field gate region(s) in a gate(s) for reduced gate layout parasitic capacitance. Related methods are also disclosed. For example, an integrated circuit may include one or more Field-Effect Transistors (FETs), such as a planar FET, a FinFET, and/or a gate-all-around (GAA) (e.g., nanowire, nanoslab, or nanosheet) FET. In exemplary aspects disclosed herein, the gate topography (e.g., height) of a gate in a circuit cell used to form gates for devices formed from the circuit cell is varied between an active region(s) of the gate (“active gate(s)”) and a field region(s) of the gate (“field gate(s)”). In this manner, the overall volume of material in the gate can be reduced due to the reduction in volume of the field gate(s) to reduce gate layout parasitic capacitance, while the volume of gate material in the active gate(s) can remain to provide the desired geometry to provide effective control of a channel of a FET and/or to not change the FET behavior. The gate layout parasitic capacitance occurs as a result of the gate located in close proximity to metal contacts and/or interconnects providing a parallel plate-like capacitance. Reducing gate layout parasitic capacitance in a circuit cell can reduce the overall parasitic capacitance of an integrated circuit formed from the circuit cell using the gate to form an active gate to achieve the desired delay performance in the integrated circuit.

Thus for example, this variation in field gate topography to reduce overall parasitic capacitance of a device formed from the circuit cell can mitigate an increase in parasitic capacitance that may result from scaling, wherein the gates may be located in closer proximity to metal contacts and/or interconnects. In this manner, a designer can scale the parasitic capacitance of the integrated circuit by controlling the field gate topography in the circuit cell. As one example of a FinFET, the designer can use the reduced field gate parasitic capacitance in a circuit cell to mitigate an increase in field gate parasitic capacitance if the number of Fins in the FET is reduced to support reduced scaling. This is because removing Fins from the circuit cell can increase the field gate regions in the circuit cell, thus increasing the field gate parasitic capacitance. Also, in examples disclosed herein, because the topography of the active gate does not have to be altered, the processes used to fabricate the active components of the FETs can remain the same.

In this regard, in one exemplary aspect, an integrated circuit is provided that comprises a diffusion region, a non-diffusion region, a semiconductor channel, and a gate. The diffusion region is disposed above a substrate and has a longitudinal axis disposed in a first direction, and the non-diffusion region is disposed above the substrate adjacent to the diffusion region. The semiconductor channel is disposed above the substrate in the diffusion region, and has a longitudinal axis disposed in the first direction. The gate comprises a metal gate material and has a longitudinal axis in a second direction substantially orthogonal to the first direction. The gate comprises and active gate region and a field gate region. The active gate region of the metal gate material is disposed in the diffusion region in contact with the semiconductor channel to form an active gate. The field gate region of the metal gate material is disposed in the non-diffusion region to form a field gate. A height of a cross-section of at least a portion of the active gate is greater than a height of a cross-section of at least a portion of the field gate.

In another exemplary aspect, a method of fabricating an integrated circuit is provided. The method comprises forming a semiconductor channel in a diffusion region above a substrate, the semiconductor channel comprising one or more channel structures each comprising a semiconductor material. The method also comprises forming a gate of a metal gate material having a substantially planar first top surface at a first height above the substrate. The gate comprises an active gate region of the metal gate material disposed adjacent to at least a portion of the semiconductor channel in the diffusion region, and a field gate region of the metal gate material disposed in a non-diffusion region adjacent to the diffusion region. The method further comprises removing the metal gate material of a first depth below the first top surface to recess the metal gate material in the active gate region to a second top surface above the substrate to form a first opening in the active gate region, and removing the metal gate material of the first depth in the field gate region to the second top surface above the substrate to form a second opening in the field gate region. The method also comprises applying a mask to protect the first opening, and exposing the second opening in the field gate region. The method further comprises removing the metal gate material in the second opening in the field gate region to a second depth below the second top surface to form a third opening in the field gate region.

In another exemplary aspect, a method of fabricating an integrated circuit is provided. The method comprises forming a material layer stack above a diffusion region and an adjacent non-diffusion region. The material layer stack comprises a gate comprising a metal gate material of a first height above a substrate. At least a portion of the metal gate material is disposed above the diffusion region to form an active gate. The material layer stack also comprises a hard mask layer above the metal gate material, a lithography material layer above the hard mask layer, and a photoresist material layer above the lithography material layer. The method comprises removing at least a portion of the material layer stack above the diffusion to form at least one opening in the material layer stack above the diffusion region down to the hard mask layer. The method further comprises filling the at least one opening with a second hard mask layer, and removing at least a portion of the lithography material layer and the photoresist material layer above the non-diffusion region. The method also comprises removing at least a portion of the metal gate material above the non-diffusion region to form a field gate at a second height above the substrate less than the first height of the active gate above the substrate.

### BRIEF DESCRIPTION OF THE FIGURES

FIG. 1 is a perspective view of an exemplary Fin Field-Effect Transistor (FET) (FinFET);

FIG. 2 is a top view of a layout of an exemplary standard cell illustrating device and layout parasitic capacitances therein;

FIG. 3A is a top view of an exemplary integrated circuit formed from a circuit cell, wherein the integrated circuits formed from a circuit cell and having an active gate in a gate in the circuit cell have a varied gate topography from a field gate in the gate for reduced gate layout parasitic capacitance;

FIGS. 3B and 3C are respective cross-sectional side views of an active gate and a field gate of a gate in the circuit cell in FIG. 3A to illustrate the varied gate topography between the active gate of the integrated circuit and the field gate in the circuit cell;

FIG. 3D is a cross-sectional side view of the gate in the circuit cell in FIG. 3A to further illustrate the varied gate topography between the active gate of the integrated circuit and the field gate in the circuit cell;

FIG. 4 is a flowchart illustrating an exemplary process of fabricating an integrated circuit in a circuit cell, such as the integrated circuit in the circuit cell in FIGS. 3A-3D, wherein the integrated circuits form an active gate in a gate in the circuit cell having a varied gate topography from a field gate in the gate from a gate material additive process for reduced gate layout parasitic capacitance;

FIGS. 5A-1 and 5A-2 illustrate respective cross-sectional side views of a first exemplary fabrication stage of a FET formed from the circuit cell in FIG. 3A having an active gate formed from a gate in the circuit cell, and an adjacent field gate region of the gate;

FIGS. 5B-1 and 5B-2 illustrate respective cross-sectional side views of a second exemplary fabrication stage of recessing metal gate material of the active gate and the field gate after the fabrication stage shown in FIGS. 5A-1 and 5A-2;

FIG. 5C illustrates a respective cross-sectional side view of a third exemplary fabrication stage of the field gate after the fabrication stage shown in FIG. 5B-2, wherein a shallow mask has been applied to protect the active gate and allow an opening to be formed above the field gate to then allow a selective recess of the field gate to be performed;

FIGS. 5D-1 and 5D-2 illustrate respective cross-sectional side views of a fourth exemplary fabrication stage filling the recessed area in the active gate and the further recessed area in the field gate with a sacrificial capping material after the fabrication stages shown in FIGS. 5B-1 and 5C;

FIG. 6A is a top view of another exemplary integrated circuit formed from a circuit cell, wherein the integrated circuit forms an active gate in a gate in the circuit cell having a varied gate topography from a field gate in the gate from a gate material removal process for reduced gate layout parasitic capacitance, and where the dielectric layer and/or work function metal layers in the field gate have also been selectively removed to reduce gate resistance;

FIGS. 6B and 6C are respective cross-sectional side views of the active gate and field gate of a gate in the circuit cell in FIG. 6A;

FIG. 6D is a cross-sectional side view of the gate in the circuit cell in FIG. 6A to further illustrate the varied gate topography between the active gate of the integrated circuit and the field gate in the circuit cell;

FIGS. 7A-1 and 7A-2 illustrate respective cross-sectional side views of another first exemplary fabrication stage of a FET formed from the circuit cell in FIG. 6A, before a metal gate material fill process is performed, wherein a shallow mask has been applied to protect the active gate and allow a further opening to be formed above the field gate to then allow further selective recessing of the field gate and removal of a dielectric layer and/or work function metal layers;

FIGS. 7B-1 and 7B-2 illustrate respective cross-sectional side views of a second exemplary fabrication stage of a FET formed from the circuit cell in FIG. 6A after a gate fill material has been disposed in active gate and field gate regions;

FIGS. 7C-1 and 7C-2 illustrate respective cross-sectional side views of a third exemplary fabrication stage of recessing the gate fill material of the active gate and the field gate after the fabrication stages shown in FIGS. 7A-2 and 7B-1;

FIG. 7D illustrates a respective cross-sectional side view of a fourth exemplary fabrication stage of the field gate after the fabrication stage shown in FIG. 7C-2, wherein the shallow mask has been re-applied to protect the active gate and allow an opening to be formed above the field gate to then allow a selective recessing of the field gate to be performed;

FIGS. 7E-1 and 7E-2 illustrate respective cross-sectional side views of a fifth exemplary fabrication stage of filling the recessed area in the active gate and the further recessed area in the field gate with a sacrificial capping material after the fabrication stages shown in FIGS. 7C-1 and 7D;

FIG. 8 is a side view of another exemplary integrated circuit formed from a circuit cell, wherein the integrated circuit formed from a circuit cell and has an active gate in a gate in the circuit cell having a varied gate topography from a field gate in the gate from a gate material removal process for reduced gate layout parasitic capacitance;

FIG. 9A illustrates a cross-sectional side view of a first exemplary fabrication stage of a gate formed from the circuit cell in FIG. 8, where a material layer stack with a lithography and photoresist material layer is shown that will be processed to form a FET;

FIG. 9B illustrates a cross-sectional side view of a second exemplary fabrication stage wherein a mask is formed above a material layer stack of the gate in FIG. 9A to form openings in the lithography and photoresist material layers recessed down to a hard mask in the material layer stack after the fabrication stage in FIG. 9A;

FIG. 9C illustrates a cross-sectional side view of a third exemplary fabrication stage wherein the recesses are filled with a hard mask material above an area where the active gates will be formed and the photoresist material layer is removed after the fabrication stage in FIG. 9B;

FIG. 9D illustrates a cross-sectional side view of a fourth exemplary fabrication stage wherein the lithography layer material is removed after the fabrication stage in FIG. 9C;

FIG. 9E illustrates a cross-sectional side view of a fifth exemplary fabrication stage wherein the gate fill material of the gate is etched in areas around the active areas protected by the hard mask to form a gate for an integrated circuit from a circuit cell with an active gate having a varied gate topography from a field gate in the gate for reduced gate layout parasitic capacitance;

FIG. 10 is a block diagram of an exemplary processor-based system that can include integrated circuits formed from a circuit cell and having an active gate in a gate in the circuit cell having a varied gate topography from a field gate in the gate for reduced gate layout parasitic capacitance, including, but not limited to, the integrated circuits and gates in FIGS. 3A, 5D-1 and 5D-2, 7E-1 and 7E-2, 8, and 9E; and

FIG. 11 is a block diagram of an exemplary wireless communications device that includes radio frequency (RF) components formed from an integrated circuit (IC), wherein any of the components therein can include integrated circuits formed from a circuit cell and having an active gate in a gate in the circuit cell having a varied gate topography from a field gate in the gate for reduced gate layout parasitic capacitance, including, but not limited to, the integrated circuits and gates in FIGS. 3A, 5D-1 and 5D-2, 7E-1 and 7E-2, 8, and 9E.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include integrated circuits employing varied gate topography between an active gate region(s) and a field gate region(s) in a gate(s) for reduced gate layout parasitic capacitance. Related methods are also disclosed. For example, an integrated circuit may include one or more Field-Effect Transistors (FETs), such as a planar FET, a FinFET, and/or a gate-all-around (GAA) (e.g., nanowire, nanoslab, or nanosheet) FET. In exemplary aspects disclosed herein, the gate topography (e.g., height) of a gate in a circuit cell used to form gates for devices formed from the circuit cell is varied between an active region(s) of the gate (“active gate(s)”) and a field region(s) of the gate (“field gate(s)”). In this manner, the overall volume of material in the gate can be reduced due to the reduction in volume of the field gate(s) to reduce gate layout parasitic capacitance, while the volume of gate material in the active gate(s) can remain to provide the desired geometry to provide effective control of a channel of a FET and/or to not change the FET behavior. The gate layout parasitic capacitance occurs as a result of the gate located in close proximity to metal contacts and/or interconnects providing a parallel plate-like capacitance. Reducing gate layout parasitic capacitance in a circuit cell can reduce the overall parasitic capacitance of an integrated circuit formed from the circuit cell using the gate to form an active gate to achieve the desired delay performance in the integrated circuit.

Thus for example, this variation in field gate topography to reduce overall parasitic capacitance of a device formed from the circuit cell can mitigate an increase in parasitic capacitance that may result from scaling, wherein the gates may be located in closer proximity to metal contacts and/or interconnects. In this manner, a designer can scale the parasitic capacitance of the integrated circuit by controlling the field gate topography in the circuit cell. As one example of a FinFET, the designer can use the reduced field gate parasitic capacitance in a circuit cell to mitigate an increase in field gate parasitic capacitance if the number of Fins in the FET is reduced to support reduced scaling. This is because removing Fins from the circuit cell can increase the field gate regions in the circuit cell, thus increasing the field gate parasitic capacitance. Also, in examples disclosed herein, because the topography of the active gate does not have to be altered, the processes used to fabricate the active components of the FETs can remain the same.

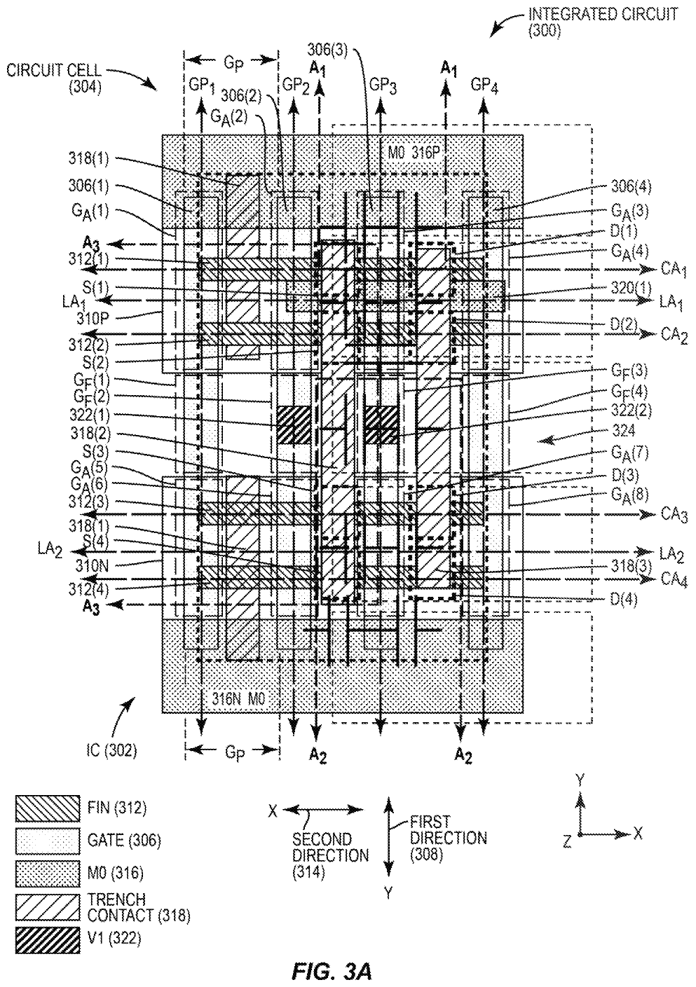

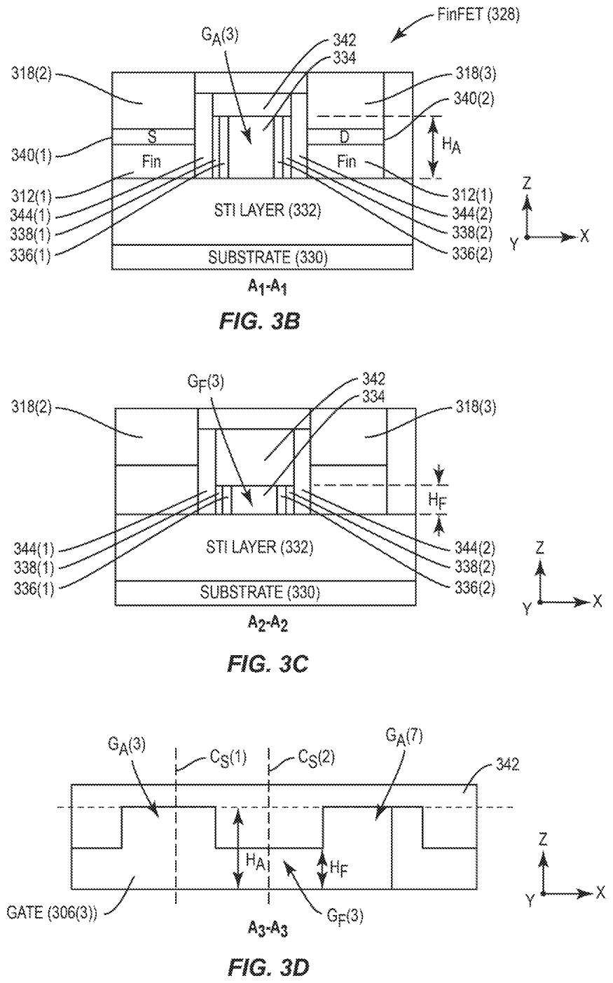

In this regard, FIG. 3A is a top view of an exemplary integrated circuit 300. As will be described below in more detail, the integrated circuit 300 includes topography variation in one or more of its field gates to reduce gate layout parasitic capacitance, and thus overall parasitic capacitance of a device formed from the integrated circuit 300. For example, reducing layout parasitic capacitance can mitigate an increase in layout parasitic capacitance that may result from scaling wherein the gates may be located in closer proximity to metal contacts and/or interconnects. The integrated circuit 300 can be included in a chip 302. In this example, the integrated circuit 300 is formed from a circuit cell 304. The circuit cell 304 is a layout of components that are commonly used to fabricate semiconductor circuits, including, but not limited to, diffusion regions, gates, semiconductor channel structures, and metal interconnect lines. In this manner, when a designer is designing a particular circuit, the designer can access the circuit cell 304 as a layout, such as from a cell library, to then design the layout of active devices and connectivity employing the same component layout in the circuit cell 304 to form the integrated circuit 300. In this manner, the circuit cell 304 can advantageously be repeated in a design over a semiconductor wafer or die to fabricate circuits where the components in the circuit cell 304 can be fabricated as part of a common fabrication process over multiple circuit cells in the wafer or die.

In this regard, as shown in FIG. 3A, the integrated circuit 300 formed from the circuit cell 304 includes gates 306(1)-306(4) each having a respective longitudinal axis GP₁, GP₂, GP₃, GP₄ disposed in a first direction 308 on a Y-axis with a defined gate pitch G_{P}. The gates 306(1)-306(4) are formed from a metal gate material. The integrated circuit 300 has four (4) gates 306(1)-306(4) available to form gates of active devices in the integrated circuit 300, but note the circuit cell 304 is not limited to this particular number of gates. The circuit cell 304 also includes diffusion regions 310P, 310N of P-type doped and N-type doped semiconductor materials, respectively, for forming semiconductor channels for P-type and N-type active devices, such as P-type metal-oxide semiconductor (MOS) (PMOS) and N-type MOS (NMOS) transistors, in the integrated circuit 300. In this example, the circuit cell 304 supports FinFETs. The diffusion regions 310P, 310N are aligned along respective longitudinal axes LA₁, LA₂ as shown in FIG. 3A. The circuit cell 304 in FIG. 3A includes semiconductor Fins 312(1)-312(4) (“Fins 312(1)-312(4)”) for forming semiconductor channels of FinFETs or gate-all-around (GAA) transistors in the integrated circuit 300. The Fins 312(1)-312(4) may be fabricated from silicon (Si) or other semiconductor material substrate such that the Fins 312(1)-312(4) are exposed. Semiconductor channels can be formed in the portion of the Fins 312(1)-312(4) located underneath the respective gates 306(1)-306(4). The Fins 312(1)-312(4) are disposed in the circuit cell 304 and have longitudinal axes CA₁, CA₂, CA₃, CA₄ in a second direction 314 of an X-axis substantially orthogonal to the first direction 308, and between first and second voltage rails 316P, 316N. In this example, two Fins 312(1), 312(2) are disposed in the P-type diffusion region 310P, and the other two Fins 312(3), 312(4) are disposed in the N-type diffusion region 310N. Thus, if desired, a two (2) Fin P-type transistor can be formed using Fins 312(1), 312(2), and a two (2) Fin N-type transistor can be formed using Fins 312(3), 312(4).

With continuing reference to FIG. 3A, the first voltage rail 316P and the second voltage rail 316N are formed in a metal zero (MO) layer. The first voltage rail 316P, being located adjacent to the P-type diffusion region 310P, is configured in this example to receive a positive supply voltage as it is common for P-type devices to be coupled to a positive supply voltage in complementary metal-oxide semiconductor (CMOS) circuits to be designed to function as a pull-up circuit. The second voltage rail 316N, being located adjacent to the N-type diffusion region 310N, is configured in this example to receive either a negative supply voltage or be coupled to a ground node as it is common for N-type devices to be designed to function as a pull-down circuit. Trench contacts 318(1)-318(3) are also formed in the first direction 308 to provide contacts to sources S(1)-S(4) and drains D(1)-D(4) of the respective Fins 312(1)-312(4). For example, the sources S(1)-S(4) and drains D(1)-D(4) disposed in the Fins 312(1)-312(4) could have been epitaxially grown on the Fins 312(1)-312(4), or the Fins 312(1)-312(4) doped to form the sources S(1)-S(4) and drains D(1)-D(4). Trench contact 318(1) has been cut. A metal line 320(1) can be formed in the first metal layer MO to provide an interconnection between gates 306(2)-306(4) and/or trench contacts 318(2), 318(3) to provide interconnections. Vias (V1) 322(1), 322(2) are shown as being formed over field regions of the gates 306(2), 306(3) in a non-diffusion region 324 outside of the P-type and N-type diffusion regions 310P, 310N to form metal contacts to the gates 306(2), 306(3). The non-diffusion region 324 is between the P-type and N-type diffusion regions 310P, 310N on the Y-axis.

With continuing reference to FIG. 3A, the gates 306(1)-306(4) each include an active gate region G_{A}(1)-G_{A}(8), also referred to as active gates G_{A}(1)-G_{A}(8), that are located above the P-type or N-type diffusion regions 310P, 310N as active areas. The active gate regions G_{A}(1)-G_{A}(4) are located above the P-type diffusion region 310P in respective gates 306(1)-306(4). The active gate regions G_{A}(5)-G_{A}(8) are located above the N-type diffusion region 310N in respective gates 306(1)-306(4). The active gate regions G_{A}(1)-G_{A}(8) can be used to form gates for active devices formed in the circuit cell 304 as part of the integrated circuit 300. The gates 306(1)-306(4) also each include field gate regions G_{F}(1)-G_{F}(4), also referred to as field gates G_{F}(1)-G_{F}(4), that are located above the non-diffusion region 324 outside of the P-type or N-type diffusion regions 310P, 310N. Parasitic capacitances occur between the active gates G_{A}(1)-G_{A}(8), respective sources S(1)-S(4) and drains D(1)-D(4), and adjacent trench contacts 318(1)-318(3), which are referred to device parasitic capacitances. Parasitic capacitances also occur between the field gates G_{F}(1)-G_{F}(4) and adjacent trench contacts 318(1)-318(3), which are referred to as layout parasitic capacitances. Gate layout parasitic capacitance occurs as a result of a gate 306(1)-306(4) located in close proximity to adjacent trench contacts 318(1)-318(3) and/or interconnects providing a parallel plate-like capacitance. These layout parasitic capacitances affect switching delay of active devices in the integrated circuit 300. These layout parasitic capacitances can also contribute to a Miller capacitance effect of active devices formed in the integrated circuit 300, which can also have a significant impact on switching delay of active devices in the integrated circuit 300. These layout parasitic capacitances may also increase if the circuit cell 304 is scaled down, because spacing between the gates 306(1)-306(4) and adjacent trench contacts 318(1)-318(3) may then be reduced.

In this regard, as will be discussed in more detail below with regard to FIGS. 3B-3D, at least one gate 306(1)-306(4) in the integrated circuit 300 in FIG. 3A has a varied gate topography between at least a portion of its respective one or more active gates G_{A}(1)-G_{A}(8) and at least a portion of its respective field gates G_{F}(1)-G_{F}(4) for reduced gate layout parasitic capacitance. In this manner, the overall volume of gate material of a respective gate 306(1)-306(4) can be reduced due to the reduction in volume of at least a portion of its respective field gates G_{F}(1)-G_{F}(4) to reduce gate layout parasitic capacitance, while the volume of gate material in its respective active gates G_{A}(1)-G_{A}(8) can remain static. This can allow the desired geometry of a gate 306(1)-306(4) to provide effective control of a semiconductor channel of an active device formed having an active gate G_{A}(1)-G_{A}(8). Reducing gate layout parasitic capacitance in the circuit cell 304 can reduce the overall parasitic capacitance of the integrated circuit 300 to achieve the desired delay performance of active devices formed in the integrated circuit 300.

To illustrate an exemplary variation in gate 306(1)-306(4) topography in the integrated circuit 300 in FIG. 3A, FIGS. 3B-3D are provided and discussed below. FIG. 3B is a cross-sectional side view along an A₁-A₁ line in the integrated circuit 300 in FIG. 3A of an active device in the form of a FinFET 328 having an active gate G_{A}(3) formed from the gate 306(3) in the integrated circuit 300 in FIG. 3A. FIG. 3C is a cross-sectional side view to illustrate along an A₂-A₂ line in the integrated circuit 300 in FIG. 3A illustrating a field gate G_{F}(3) of the gate 306(3) in the integrated circuit 300. FIG. 3D is a cross-sectional side view along an A₃-A₃ line of the gate 306(3) showing both active gates G_{A}(3), G_{A}(7) and the field gate G_{F}(3) therein to further illustrate the varied gate topography in the gate 306(3).

As shown in FIG. 3B, the cross-sectional side view of the FinFET 328 formed in the integrated circuit 300 along the A₁-A₁ line includes a substrate 330 and a shallow trench isolation (STI) layer 332 disposed above the substrate 330. The active gate G_{A}(3) formed from the gate 306(3) in the P-type diffusion region 310P is shown above the STI layer 332. The active gate G_{A}(3) includes a metal gate material 334 surrounded by work function metal layers 336(1), 336(2) on each side of the metal gate material 334 on the X-axis. For example, the metal gate material 334 may be Tungsten (W), Aluminum (Al), Cobalt (Co), or Ruthenium (Ru), as examples. The work function metal layers 336(1), 336(2) are work function metal materials that can be Titanium (Ti), Nickel (Ni), Aluminum (Al), Titanium Nitride (TiN), Titanium Aluminum (TiAl), or Aluminum Nitride (AlN) as examples. Dielectric layers 338(1), 338(2), which may be a Hafnium Oxide (HfO₂) material, surround the respective work function metal layers 336(1), 336(2) on the X-axis. The active gate G_{A}(3) is disposed around a portion of the Fin 312(1) wherein a semiconductor channel is formed in the Fin 312(1), but not the entire portion of the Fin 312(1). Alternatively, the active gate G_{A}(3) could be disposed around the entire portion of the Fin 312(1) or substantially the entire portion of the Fin 312(1) to form a gate-all-around (GAA) transistor, which could be a nanowire transistor or nanoslab transistor with the Fin 312(1) forming the nanowire or nanoslab. A source S is disposed in a first region 340(1) in or above the Fin 312(1) not surrounded by the active gate G_{A}(3) adjacent to a first side of the active gate G_{A}(3). A drain D disposed in a second region 340(2) in or above the Fin 312(1) not surrounded by the active gate G_{A}(3) on the opposite of the first side of the active gate G_{A}(3) from the source S. For example, the source S and drain D may be epitaxially grown on the respective first and second regions 340(1), 340(2) of the Fin 312(1), or the first and second regions 340(1), 340(2) of the Fin 312(1) may be doped to form the source S and drain D. A gate capping material 342, such as a Silicon Nitride (SiN) material, is disposed above the active gate G_{A}(3) to protect the active gate G_{A}(3). The gate capping material 342 may be planarized to have a substantially planar surface. Spacers 344(1), 344(2), which may be a Silicon Oxide Carbon (SiOC) material, are formed around the dielectric layers 338(1), 338(2). The trench contacts 318(2), 318(3) are formed above the source S and drain D to form contacts with the source S and drain D to allow interconnections in upper metal layers thereto. The trench contacts 318(2), 318(3) may be thought of as source and drain contacts.

FIG. 3C is a cross-sectional side view to illustrate along the A₂-A₂ line in the integrated circuit 300 in FIG. 3A illustrating a field gate G_{F}(3) of the gate 306(3) in the integrated circuit 300. The field gate G_{F} (3) includes the metal gate material 334 surrounded by the work function metal layers 336(1), 336(2) and the dielectric layers 338(1), 338(2) like the active gate G_{A}(3) illustrated in FIG. 3B. However, the height H_{F} of the field gate G_{F}(3) is smaller than the height H_{A} of the active gate G_{A}(3). Thus, in this example, the cross-sectional area of the field gate G_{F}(3) is also less than the cross-sectional area of the active gate G_{A}(3) based on the difference in their heights H_{F} and H_{A} in this example. The gate capping material 342 fills in the extra void by the field gate G_{F}(3) having the height H_{F} less than height H_{A}. In this manner, the parasitic capacitance between the field gate G_{F}(3) and the trench contacts 318(2), 318(3) will be less due to the reduced volume of the field gate G_{F}(3) due to its reduced height H_{F} than it would otherwise be if the field gate G_{F}(3) were taller, such as the same height H_{A} of the active gate G_{A}(3). This is shown in FIG. 3D, which is a cross-sectional side view of the gate 306(3) showing both active gates G_{A}(3), G_{A}(7) and the field gate G_{F}(3) therein to further illustrate the varied gate topography in the gate 306(3).

Thus, this variation in gate 306(3) topography between the active gates G_{A}(3), G_{A}(7) and the field gate G_{F}(3) in the examples of FIGS. 3A-3D can reduce the gate layout parasitic capacitance in the circuit cell 304. This can mitigate an increase in parasitic capacitance that may result from scaling wherein the gates 306(1)-306(4) in the circuit cell 304 may be located in closer proximity to the trench contacts 318(1)-318(3) and/or other interconnects. In this manner, a designer can scale the parasitic capacitance of the integrated circuit 300 by controlling the field gate G_{F}(1)-G_{F}(4) topography in the circuit cell 304. As in the example of the FinFET 328 in FIG. 3B, the designer can use the reduced parasitic capacitance of the field gate G_{F}(3) to mitigate an increase in field gate parasitic capacitance if the number of Fins 312(1)-312(4) in the FinFET 328 is reduced to support reduced scaling. This is because removing Fins 312(1)-312(4) from the circuit cell 304 can increase the field gates G_{F}(1)-G_{F}(4) in the circuit cell 304, thus increasing the field gate parasitic capacitance. Also, in examples disclosed herein of the gate 306(3) in FIGS. 3A-3D, because the topography of the active gates G_{A}(3), G_{A}(7) therein does not have to be altered, the processes used to fabricate the active components of the FinFET 328 can remain the same if desired.

With reference back to FIG. 3D, in this example, an area of a cross-section C_{S}(1) of at least a portion of the active gate G_{A}(3) is greater than an area of a cross-section C_{S}(2) of at least a portion of the field gate G_{F}(3) due to the difference in their heights H_{A}, H_{F}. The height H_{A} of the active gate G_{A}(3) may be between 30-90 nanometers (nm) as an example. The height H_{F} of the field gate G_{F}(3) may be between 20-40 nanometers (nm) as an example. A ratio of the area of the cross-section C_{S}(1) of at least a portion of the active gate G_{A}(3) to the area of the cross-section C_{S}(2) of at least a portion of the field gate G_{F}(3) may be at least 1.5 (one and half) as an example. A ratio of the height H_{A} of the cross-section C_{S}(1) of at least a portion of the active gate G_{A}(3) to the height H_{F} of the cross-section C_{S}(2) of at least a portion of the field gate G_{F}(3) may be at least 1.5 (one and half) as an example.

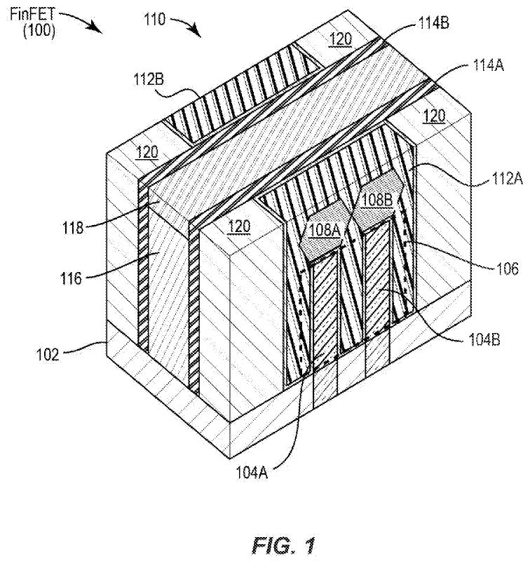

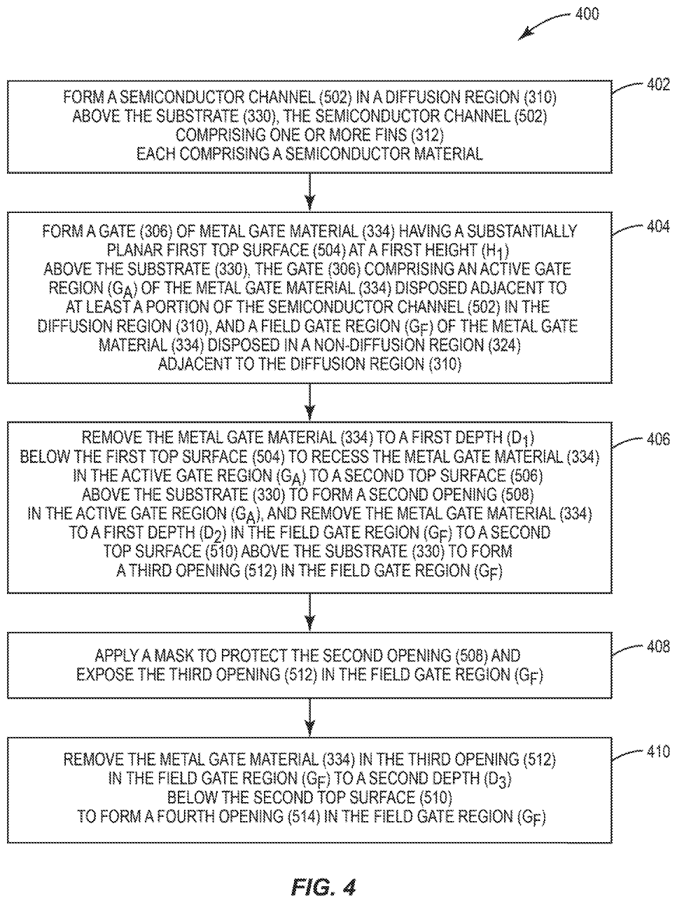

FIG. 4 is a flowchart illustrating an exemplary process 400 of fabricating an integrated circuit in a circuit cell, like the integrated circuit 300 in the circuit cell 304 in FIGS. 3A-3D, wherein the integrated circuit 300 forms an active gate in a gate in the circuit cell 304 having a varied gate topography from a field gate in the gate from a gate material additive process for reduced gate layout parasitic capacitance. The process 400 in FIG. 4 will be described in conjunction with exemplary fabrication stages of the integrated circuit 300 in FIGS. 5A-1-5D-2 below. Common elements and/or materials between the integrated circuit 300 in FIGS. 3A-3D and the fabrication stages shown in FIGS. 5A-1-5D-2 of the integrated circuit 300 are shown with common element numbers, and thus will not be re-described.

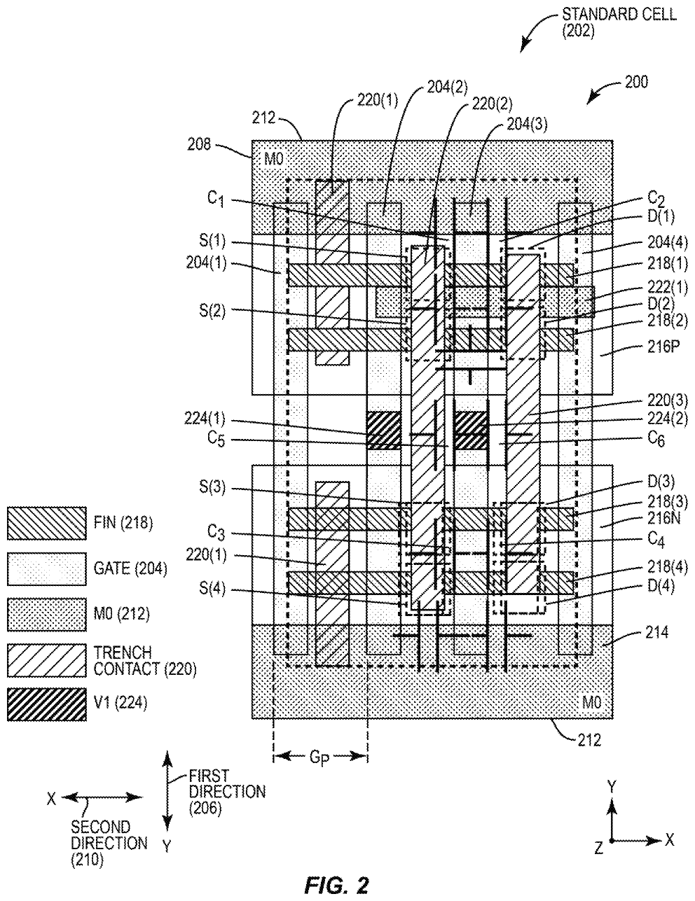

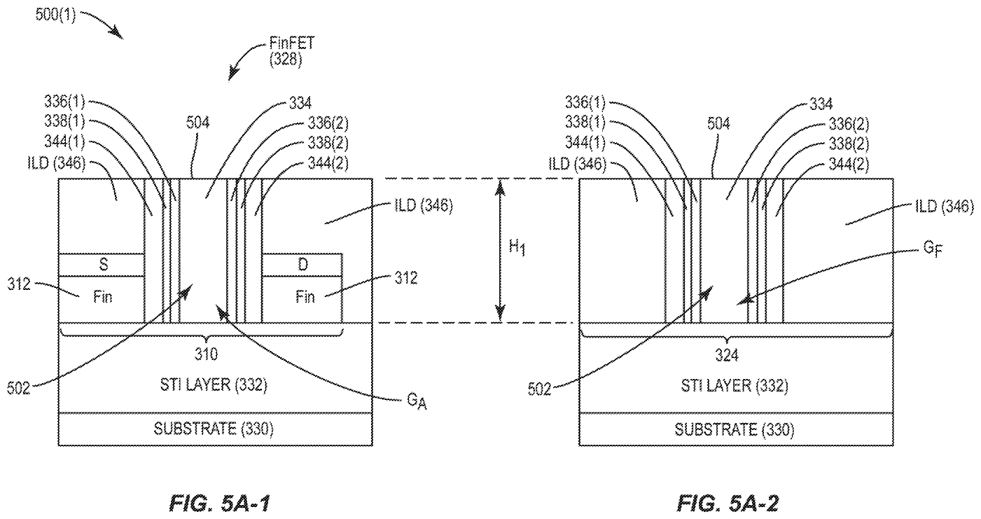

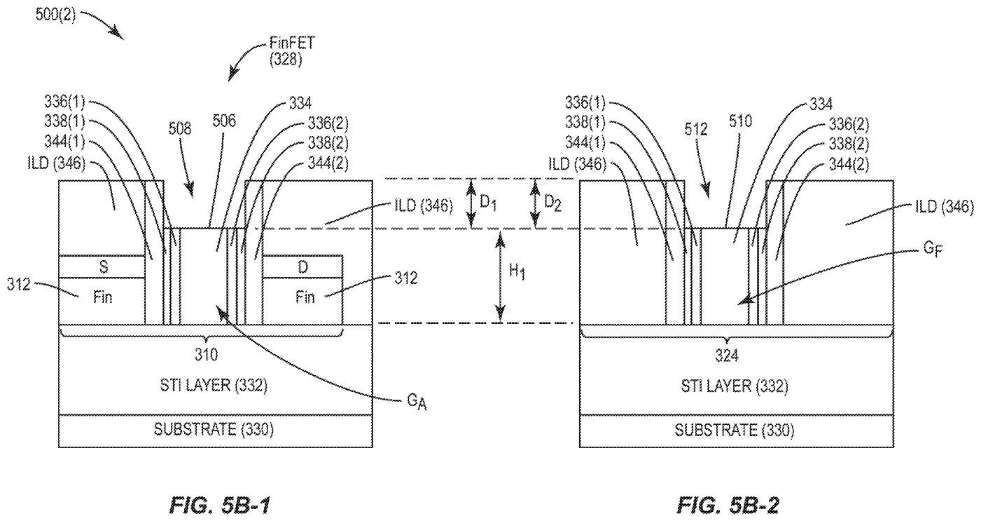

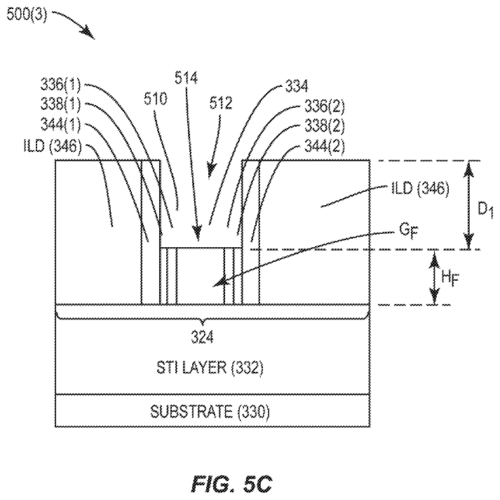

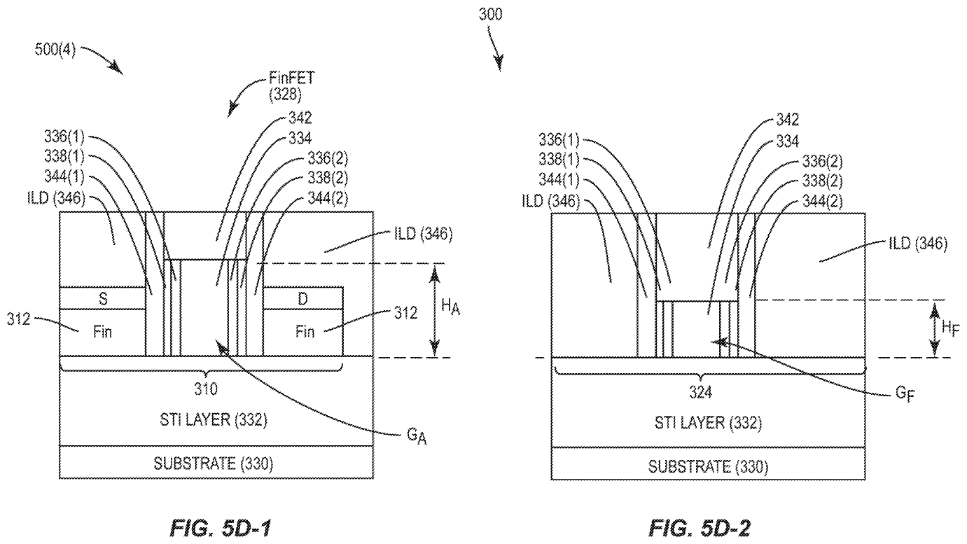

In this regard, with reference to FIG. 5A-1, a first fabrication step to fabricate the integrated circuit 300 can to be form a semiconductor channel 502 in a diffusion region 310 above the substrate 330, wherein the semiconductor channel 502 comprises one or more Fins 312 (as channel structures) each comprising a semiconductor material (block 402 in FIG. 4). A second fabrication step to fabricate the integrated circuit 300 can be performed to form a gate 306 (see FIG. 3A) of metal gate material 334 having a substantially planar first top surface 504 at a first height H₁ above the substrate 330 and the STI layer 332 (block 404 in FIG. 4). FIGS. 5A-1 and 5A-2 illustrate respective cross-sectional side views of a first exemplary fabrication stage 500(1) of the FinFET 328 formed from the circuit cell 304 as the integrated circuit 300 in FIG. 3A after these steps were performed. As shown in FIG. 5A-1, the gate 306 includes the active gate region G_{A} of the metal gate material 334 disposed adjacent to at least a portion of the semiconductor channel 502 in the diffusion region 310, and a field gate region G_{F} in FIG. 5A-2 of the metal gate material 334 is disposed in a non-diffusion region 324 adjacent to the diffusion region 310. The active gate region G_{A} and the field gate region G_{F} both include the metal gate material 334 surrounded by the work function metal layers 336(1), 336(2), which are then surrounded by the dielectric layers 338(1), 338(2) at the first height H₁. In this example, the source S and drain D of the FinFET 328 are epitaxially grown above the portions of the Fin 312 not surrounded by the active gate region G_{A}. Spacers 344(1), 344(2) are formed around the active gate region G_{A}. The spacers 344(1), 344(2) may have been formed adjacent to the gate 306 in a previous step wherein an opening was created therebetween to dispose the dielectric layers 338(1), 338(2), the work function metal layers 336(1), 336(2), and the metal gate material 334. An interlayer dielectric (ILD) 346 surrounds the source S and drain D and active gate region G_{A}.

With reference back to FIG. 4, and as shown in fabrication stage 500(2) in FIGS. 5B-1 and 5B-2, a next fabrication step may be to remove the metal gate material 334 to a first depth D₁ below the first top surface 504 to recess the metal gate material 334 in the active gate region G_{A} to a second top surface 506 above the substrate 330 to form a second opening 508 in the active gate region G_{A}, as shown in FIG. 5B-1 (block 406 in FIG. 4). This next fabrication step may also include removing the metal gate material 334 to a first depth D₂ in the field gate region G_{F} to a second top surface 510 above the substrate 330 to form a third opening 512 in the field gate region G_{F}, as shown in FIG. 5B-2 (block 406 in FIG. 4). These steps can be performed to prepare the active gate region G_{A} and the field gate region G_{F} to be of the desired height based on design considerations for active gate region G_{A} control of the semiconductor channel 502 and to prepare for a capping material to be disposed above the active gate region G_{A} and the field gate region G_{F} in a later processing step to protect the active gate region G_{A} and the field gate region G_{F}.

With reference back to FIG. 4, and as shown in fabrication stage 500(3) in FIG. 5C, a next fabrication step may be to apply a mask (e.g., through a lithography process) to protect the second opening 508 to further recess the metal gate material 334 in the field gate region G_{F} to reduce gate layout parasitic capacitance as previously discussed (block 408 in FIG. 4). In this regard, the application of the mask is used to expose the third opening 512 in the field gate region G_{F} to the metal gate material 334 from the field gate region G_{F} (block 408 in FIG. 4). This is shown in FIG. 5C, which illustrates the field gate region G_{F}. No additional metal gate material 334 need be removed from the active gate region G_{F} unless desired. Next, the metal gate material 334 in the field gate region G_{F} exposed through the third opening 512 may be removed (e.g., etched) to a third depth D₃ below the second top surface 510 to form a fourth opening 514 in the field gate region G_{F} (block 410 in FIG. 4). This reduces the height of the field gate region G_{F} to height H_{F} above the substrate 330 and reduces the volume of the metal gate material 334 in the field gate region G_{F} to reduce gate layout parasitic capacitance as previously discussed. FIGS. 5D-1 and 5D-2 illustrate respective cross-sectional side views of a fourth exemplary fabrication stage 500(4). In this fabrication stage 500(4), the second opening 508 in the active gate region G_{A} and the fourth opening 514 in the field gate region G_{F} are filled with a gate capping material 342 to protect the active gate region G_{A} and the field gate region G_{F}. The gate capping material 342 may be planarized to have a substantially planar surface. The FinFET 328 is formed as shown in FIG. 5D-1.

As shown in FIGS. 3A-3D and illustrated in the exemplary fabrication stages 500(1)-500(4) in FIGS. 5A-1-5D-2, the field gate region G_{F} is processed to reduce gate layout parasitic capacitance in the integrated circuit 300. However, the work function metal layers 336(1), 336(2) and the dielectric layers 338(1), 338(2) are still included in the final processed field gate region G_{F}. The gate layout parasitic resistance in the integrated circuit 300 may be further reduced if the work function metal layers 336(1), 336(2) and the dielectric layers 338(1), 338(2) were also completely or substantially removed from the final processed field gate region G_{F}, and replaced with additional metal gate material 334. The metal gate material 334 has a lower resistance than the work function metal layers 336(1), 336(2) and the dielectric layers 338(1), 338(2). The additional volume of the metal gate material 334 in the field gate region G_{F} reduces gate layout parasitic resistance in the integrated circuit 300, while the active gate region G_{A} retains the work function metal layers 336(1), 336(2) and dielectric layers 338(1), 338(2) to effectively isolate the metal gate material 334 from the semiconductor channel 502 of the FinFET 328 to provide effective control of the semiconductor channel 502 and/or to not otherwise change the FinFET 328 behavior from previous layout designs. Reducing gate layout parasitic resistance can reduce the overall parasitic resistance of the integrated circuit 300 to reduce current (I) resistance (R) (IR) drop to achieve the desired drive strength performance of the FinFET 328 in the integrated circuit 300.

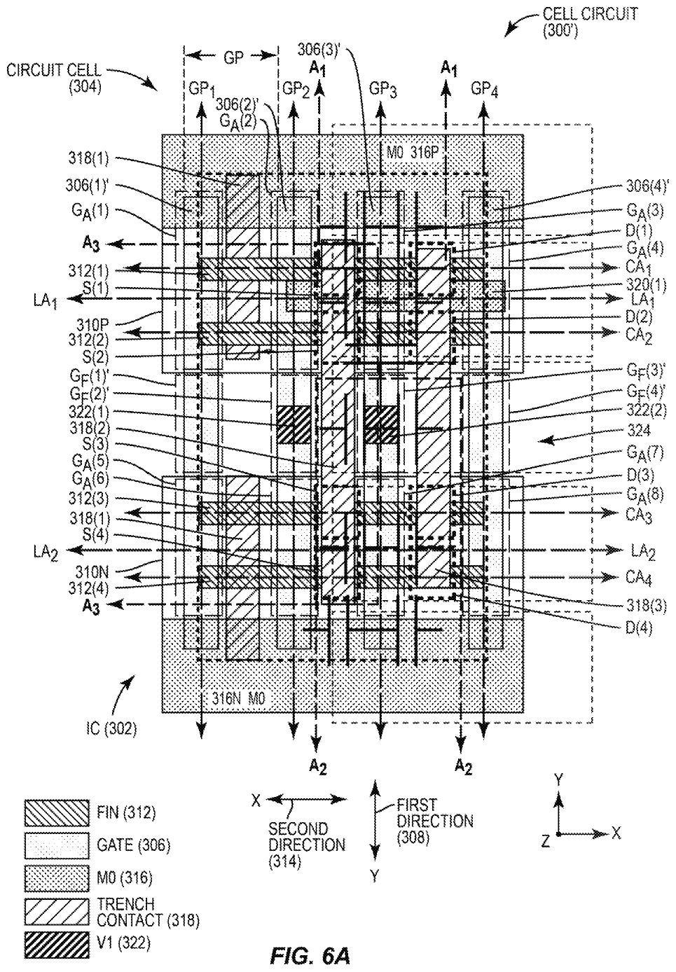

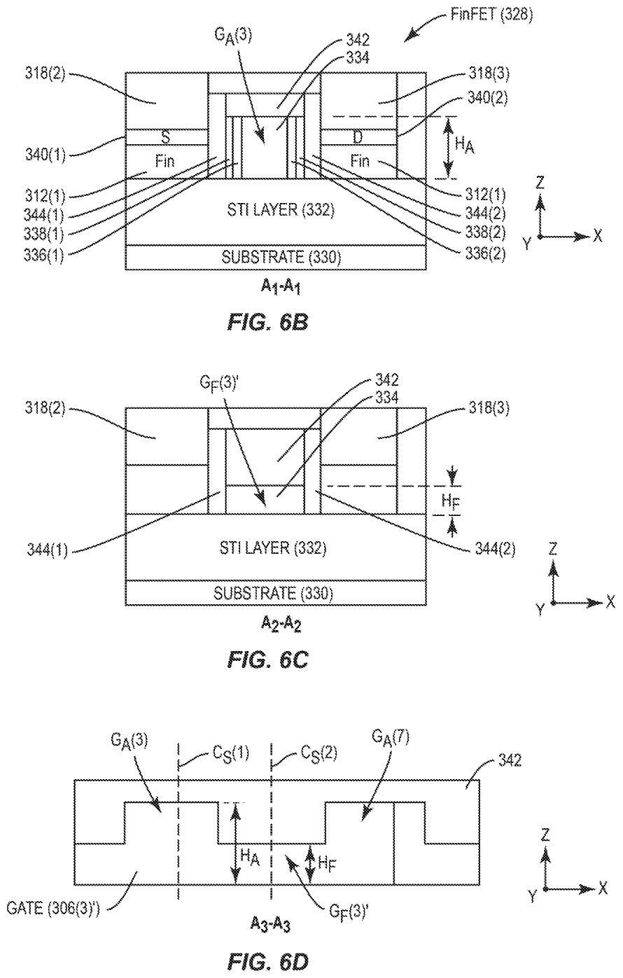

In this regard, FIG. 6A is a top view an integrated circuit 300′ also formed from the circuit cell 304 that is illustrated in FIG. 3A and previously discussed. However, as discussed below and illustrated in FIGS. 6A-6D, the integrated circuit 300′ includes a field gate region G_{F}′ in gate 306′ that is formed from an additional removal process where the dielectric layers 338(1), 338(2) and work function metal layers 336(1), 336(2) in the field gate region G_{F}′ have also been selectively removed to reduce gate layout parasitic resistance. Common elements and/or materials between the integrated circuit 300 in FIGS. 3A-3D and the integrated circuit 300′ in FIGS. 6A-6D are shown with common element numbers, and thus will not be re-described. FIGS. 6B and 6C are respective cross-sectional side views of an active gate region G_{A} and the field gate region G_{F}′ of the gate 306′ in the integrated circuit 300′ in FIG. 6A. FIG. 6D is a cross-sectional side view of the gate 306′ in the integrated circuit 300′ in FIG. 6A to further illustrate the varied gate topography between the active gate region G_{A} and the field gate region G_{F}′ in the integrated circuit 300′.

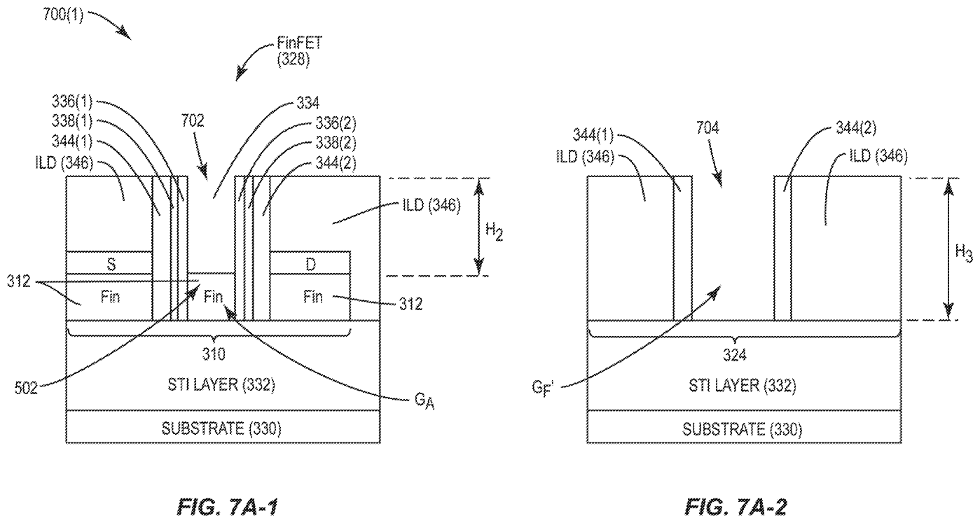

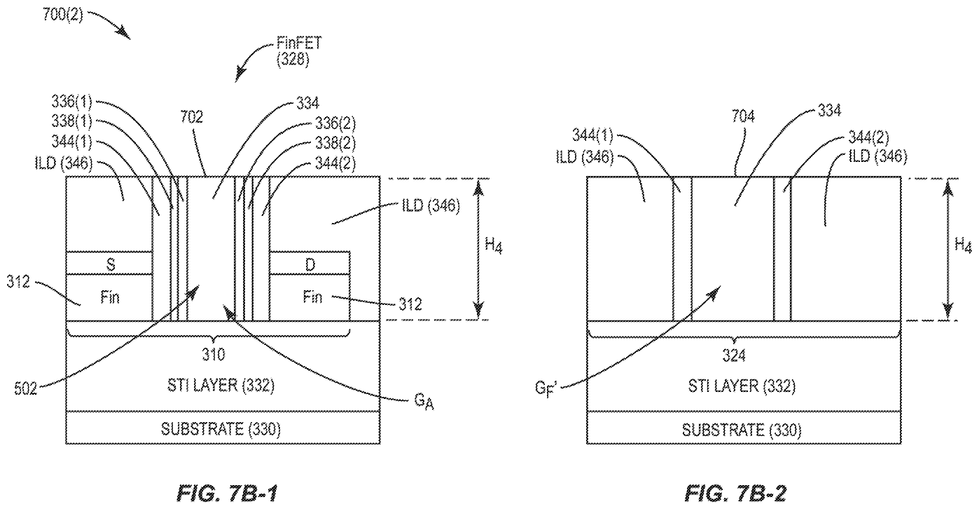

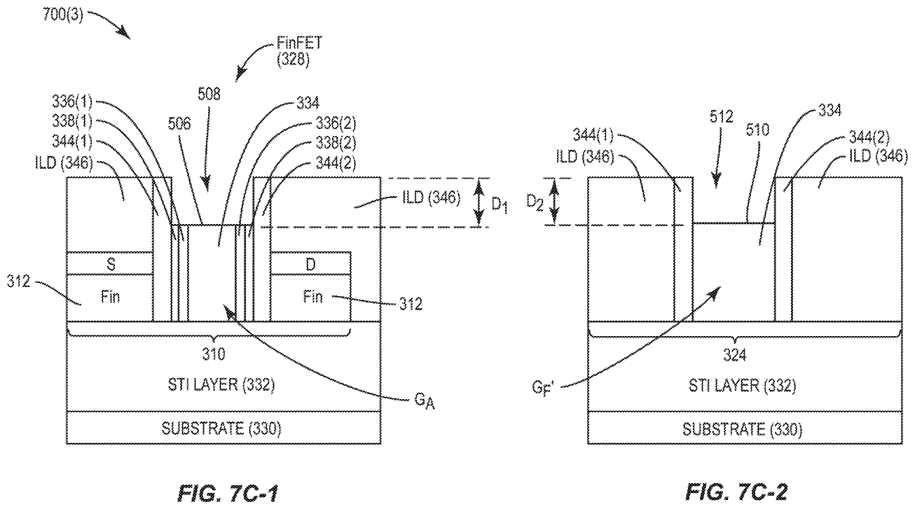

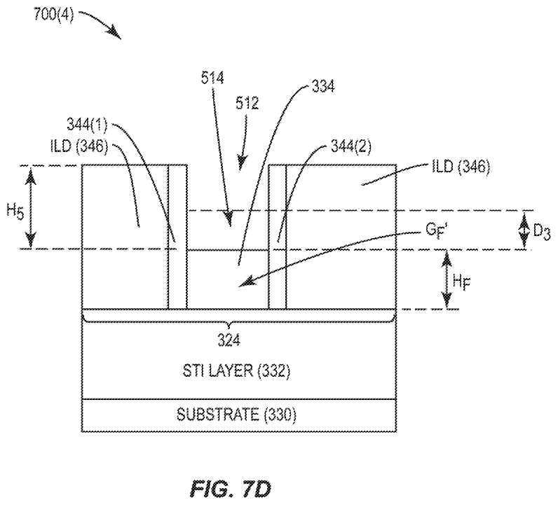

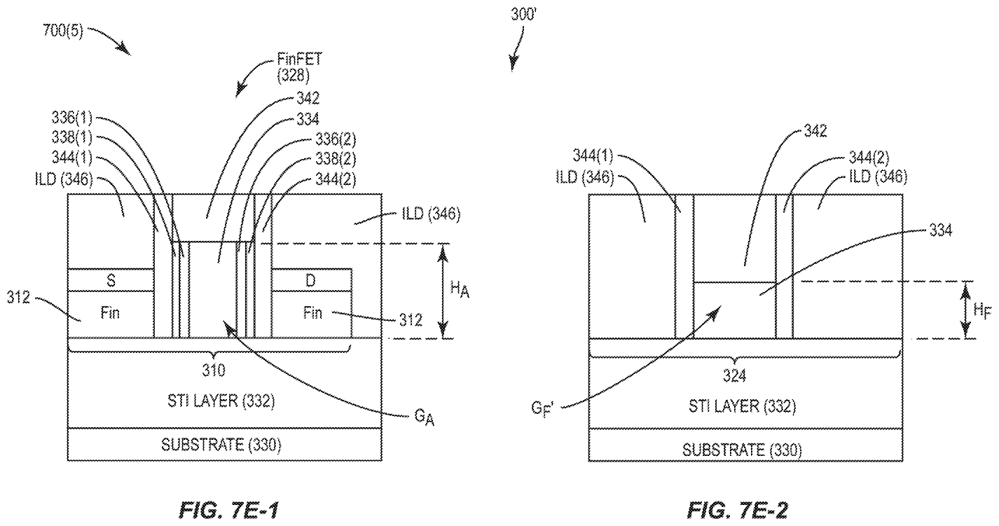

In this regard, FIGS. 7A-1 and 7A-2 illustrate respective cross-sectional side views of a first exemplary fabrication stage 700(1) of the FinFET 328 formed from the circuit cell 304 in the integrated circuit 300′ in FIG. 6A after active and field dummy gate materials have been removed from respective openings 702, 704 down to respective heights H₂ and H₃ formed in the respective active gate region G_{A} and the field gate region G_{F}′. Note that the work function metal layers 336(1), 336(2) and the dielectric layers 338(1), 338(2) are removed in the field gate region G_{F}′ in FIG. 7A-2, but not in the active gate region G_{A} in FIG. 7A-1. A mask is applied as part of a lithography process to protect the field gate region G_{F}′ to form an opening above the active gate region G_{A} to then remove the dummy gate material in the active gate region G_{A} as shown in FIG. 7A-1 to form the opening 702. Then, another mask is applied as part of a lithography process to protect the active gate region G_{A} to form an opening above the field gate region G_{F}′ to then remove the dummy gate material as well as the work function metal layers 336(1), 336(2) and the dielectric layers 338(1), 338(2) in the field gate region G_{F}′ as shown in FIG. 7A-2 to form the opening 704. Thereafter, as shown in a second fabrication stage 700(2) in FIGS. 7B-1 and 7B-2, the openings 702, 704 in the active gate region G_{A} and the field gate region G_{F}′ are filled with metal gate material 334 to height H₄ above the STI layer 332. The second fabrication stage 700(2) is similar to the fabrication stage 500(1) in FIGS. 5A-1 and 5A-2, except that the work function metal layers 336(1), 336(2) and the dielectric layers 338(1), 338(2) in the field gate region G_{F}′ are removed to reduce gate layout parasitic resistance as discussed above.

A next fabrication stage 700(3) for the FinFET 328 is illustrated in FIGS. 7C-1 and 7C-2. This fabrication stage 700(3) is the same as fabrication stage 500(2) in FIGS. 5B-1 and 5B-2 with common elements shown with common element numbers except that the work function metal layers 336(1), 336(2) and the dielectric layers 338(1), 338(2) in the field gate region G_{F}′ are removed to reduce gate layout parasitic resistance as discussed above. Thus, the previous discussion of the fabrication stage 500(2) in FIGS. 5B-1 and 5B-2 is applicable to the fabrication stage 700(3) in FIGS. 7C-1 and 7C-2.

A next fabrication stage 700(4) for the FinFET 328 is illustrated in FIG. 7D. This fabrication stage 700(4) is the same as fabrication stage 500(3) in FIG. 5C with common elements shown with common element numbers except that the work function metal layers 336(1), 336(2) and the dielectric layers 338(1), 338(2) in the field gate region G_{F}′ are removed to reduce gate layout parasitic resistance as discussed above. The gate metal material 334 of the field gate G_{F}′ is removed further by depth D₃ to its final height of H_{F}. Thus, the previous discussion of the fabrication stage 500(3) in FIG. 5C is applicable to the fabrication stage 700(4) in FIG. 7D.

A next fabrication stage 700(5) for the FinFET 328 is illustrated in FIGS. 7E-1 and 7E-2. This fabrication stage 700(5) is the same as fabrication stage 500(4) in FIGS. 5D-1 and 5D-2 with common elements shown with common element numbers except that the work function metal layers 336(1), 336(2) and the dielectric layers 338(1), 338(2) in the field gate region G_{F}′ are removed to reduce gate layout parasitic resistance as discussed above. Thus, the previous discussion of the fabrication stage 500(4) in FIGS. 5D-1 and 5D-2 is applicable to the fabrication stage 700(5) in FIGS. 7E-1 and 7E-2.

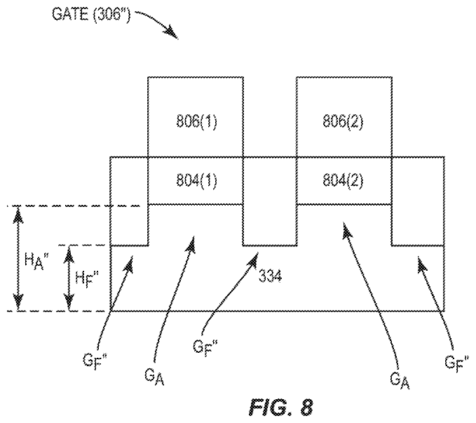

The fabrication processes for forming the gates 306, 306′ in the integrated circuits 300, 300′ in FIGS. 3A-3D and FIGS. 6A-6D above use an active removal and fill process to form the metal gate material 334 at the desired volume for the field gate region G_{F}, G_{F}′ to reduce the gate layout parasitic capacitance. A fabrication process can also be employed to form the topography of a gate by a non-active, removal process for the metal gate material 334 at the desired volume for the field gate region G_{F}, G_{F}′ to reduce the gate layout parasitic capacitance. In this regard, FIG. 8 a side view of another exemplary gate 306″ formed in a circuit cell, such as the circuit cell 304, having an active gate G_{A} in the gate 306″ having a varied gate topography from a field gate(s) G_{F}″ from a gate material removal process for reduced gate layout parasitic capacitance. As shown in FIG. 8, the gate 306″ is formed by a metal gate material 334 that includes active gate regions G_{A} and field gate regions G_{F}″. The field gate regions G_{F}″ are of a height H_{F}″ and the active gate regions G_{A} are of a height H_{A}″. The features regarding differences in cross-sectional areas and/or heights between the height H_{F}″ and the active gate regions G_{A} can be the same as previously described for the gate 306 in FIGS. 3A-3D. Hard mask layers 804(1), 804(2) are disposed above the active gate regions G_{A} as a remnant of a previous continuous hard mask layer formed over the entire gate 306″ before etching processes were performed to form the field gate regions G_{F}″ at the lower height H_{F}″. Hard mask layers 806(1), 806(2) are disposed above the active gate regions G_{A} as a function of the fabrication process to protect the active gate regions G_{A} during an etching process of the field gate regions G_{F}″.

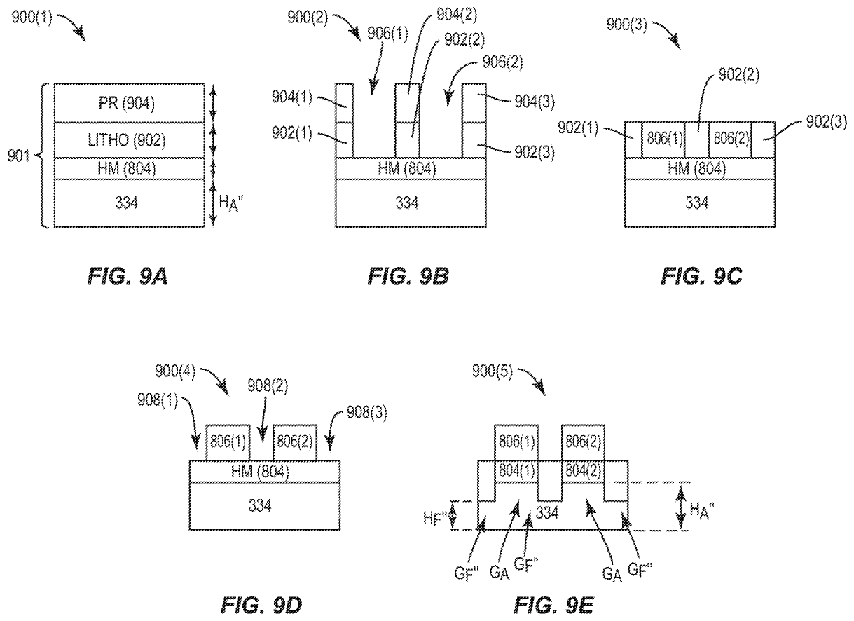

FIGS. 9A-9E illustrate an exemplary fabrication process to fabricate the gate 306″ in FIG. 8. FIG. 9A illustrates a cross-sectional side view of a first exemplary fabrication stage 900(1) of the gate 306″ in FIG. 8. A material layer stack 901 is formed above a diffusion region and an adjacent non-diffusion region, such as the diffusion regions 310P, 310N and non-diffusion region 324 in the circuit cell 304 in FIG. 3A. The material layer stack 901 comprises the metal gate material 334, a hard mask layer (HM) 804 disposed above the metal gate material 334, a lithography material layer (LITHO) 902 disposed above the hard mask layer 804 and a photoresist material layer (PR) 904 disposed above the lithography material layer 902. The height H_{A}″ of the metal gate material 334 can be the ending height of the active gate regions G_{A} that will be formed in the material layer stack 901.

As shown in FIG. 9B, in a second fabrication stage 900(2), a mask can be applied above the material layer stack 901 and an etch process can be performed to expose one or more portions of the material layer stack 901 above the diffusion region in openings 906(1), 906(2) where the active gate regions G_{A} are desired to be formed. The lithography material layer 902 and the photoresist material layer 904 are removed by openings 906(1), 906(2) to leave separate segments of lithography material layers 902(1)-902(3) and photoresist material layers 904(1)-904(3). Then, in a third fabrication stage 900(3) as shown in FIG. 9C, openings 906(1), 906(2) are filled with another hard mask material to form hard mask layers 806(1), 806(2) and the remaining portions of the photoresist material layer 904 are removed. The top surface of the hard mask layers 806(1), 806(2) may be planarized, such as through a chemical mechanical planarization (CMP) process. Then, in a fourth fabrication stage 900(4) as shown in FIG. 9D, a mask can be applied above the material layer stack 901 and the remaining portions of the lithography material layer 902 are removed. This leaves the additional hard mask layers 806(1), 806(2) disposed above the hard mask layer 804. Openings 908(1)-908(3) are formed as a result of the removing of the remaining portions of the lithography material layer 902. In a fabrication stage 900(5) in FIG. 9E, a portion of the hard mask layer 804 and the metal gate material 334 is further etched in the openings 908(1)-908(3) to form the field gate regions G_{F}″ at a height H_{F}″ less than the height H_{A}″ of the active gate region G_{A}. FIG. 9E is the gate 306″ in FIG. 8.

An integrated circuit formed from a circuit cell, wherein at least a portion of dielectric layers and/or work function metal layers present in an active gate of a gate are not present in a field gate of the gate to increase gate material in the field gate to reduce gate layout parasitic resistance in the circuit cell, can also be employed in planar and GAA transistors. An integrated circuit formed from a circuit cell and having an active gate in a gate in the circuit cell having a varied gate topography from a field gate in the gate for reduced gate layout parasitic capacitance, including, but not limited to, the integrated circuits 300, 300′ and gates 306, 306′, 306″ in FIGS. 3A, 5D-1 and 5D-2, 7E-1 and 7E-2, 8, and 9E, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

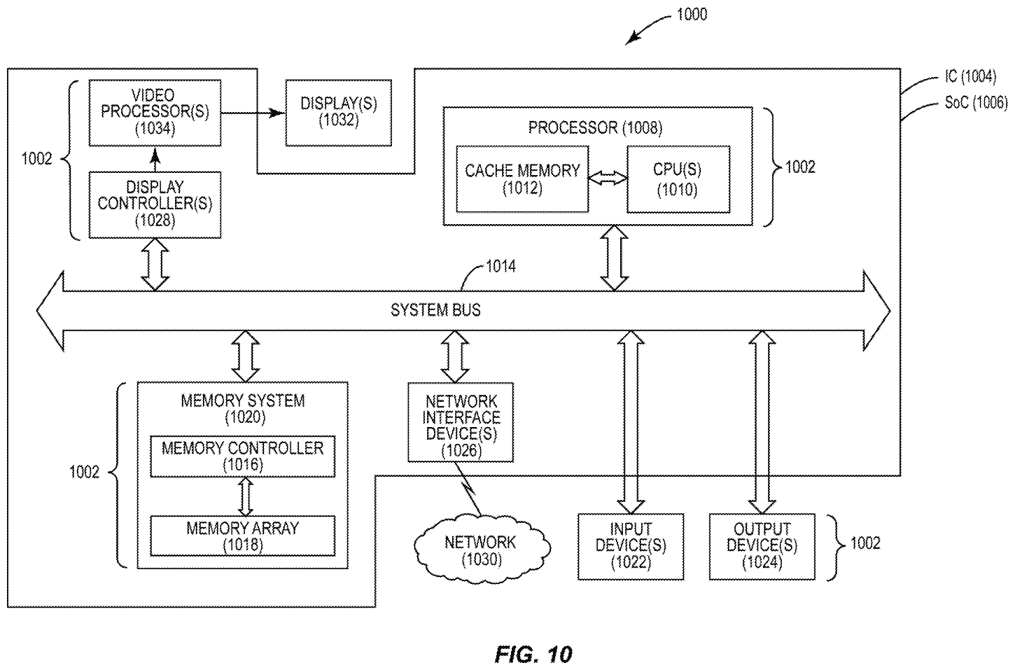

In this regard, FIG. 10 illustrates an example of a processor-based system 1000 that can include integrated circuits 1002 formed from a circuit cell and having an active gate in a gate in the circuit cell having a varied gate topography from a field gate in the gate for reduced gate layout parasitic capacitance, including, but not limited to, the integrated circuits 300, 300′ and gates 306, 306′, 306″ in FIGS. 3A, 5D-1 and 5D-2, 7E-1 and 7E-2, 8, and 9E, and according to any aspects disclosed herein. In this example, the processor-based system 1000 may be formed as an IC 1004 in a system-on-a-chip (SoC) 1006. The processor-based system 1000 includes a processor 1008 that includes one or more central processor units (CPUs) 1010, which may also be referred to as CPU or processor cores. The processor 1008 may have cache memory 1012 coupled to the processor(s) 1008 for rapid access to temporarily stored data. As an example, the cache memory 1012 could include integrated circuits 1002 formed from a circuit cell and having an active gate in a gate in the circuit cell having a varied gate topography from a field gate in the gate for reduced gate layout parasitic capacitance, including, but not limited to, the integrated circuits 300, 300′ and gates 306, 306′, 306″ in FIGS. 3A, 5D-1 and 5D-2, 7E-1 and 7E-2, 8, and 9E, and according to any aspects disclosed herein. The processor 1008 is coupled to a system bus 1014 and can intercouple master and slave devices included in the processor-based system 1000. As is well known, the processor 1008 communicates with these other devices by exchanging address, control, and data information over the system bus 1014. For example, the processor 1008 can communicate bus transaction requests to a memory controller 1016 as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples. Each of the memory system 1020, the one or more input devices 1022, the one or more output devices 1024, the one or more network interface devices 1026, and the one or more display controllers 1028 can include integrated circuits 1002 formed from a circuit cell and having an active gate in a gate in the circuit cell having a varied gate topography from a field gate in the gate for reduced gate layout parasitic capacitance, including, but not limited to, the integrated circuits 300, 300′ and gates 306, 306′, 306″ in FIGS. 3A, 5D-1 and 5D-2, 7E-1 and 7E-2, 8, and 9E, and according to any aspects disclosed herein. The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The processor 1008 may also be configured to access the display controller(s) 1028 over the system bus 1014 to control information sent to one or more displays 1032. The display controller(s) 1028 sends information to the display(s) 1032 to be displayed via one or more video processors 1034, which process the information to be displayed into a format suitable for the display(s) 1032. The display(s) 1032 can include any type of display, including, but not limited to, a cathode ray tube (CRT), a liquid crystal display (LCD), a plasma display, a light emitting diode (LED) display, etc. The display controller(s) 1028, display(s) 1032, and/or the video processor(s) 1034 can include integrated circuits 1002 formed from a circuit cell and having an active gate in a gate in the circuit cell having a varied gate topography from a field gate in the gate for reduced gate layout parasitic capacitance, including, but not limited to, the integrated circuits 300, 300′ and gates 306, 306′, 306″ in FIGS. 3A, 5D-1 and 5D-2, 7E-1 and 7E-2, 8, and 9E, and according to any aspects disclosed herein.

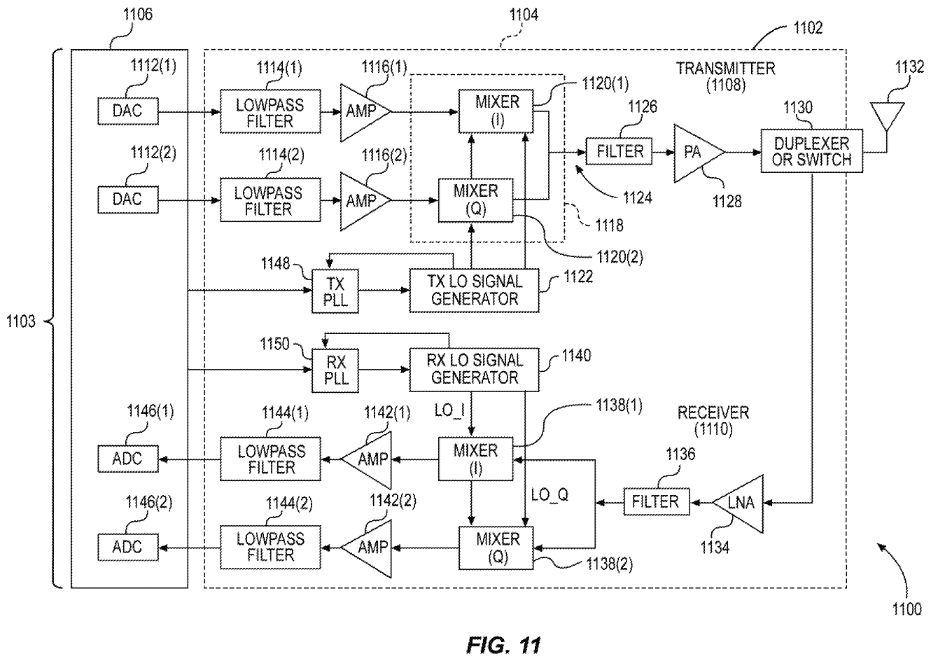

FIG. 11 illustrates an exemplary wireless communications device 1100 that includes radio frequency (RF) components formed from an IC 1102, wherein any of the components therein can include integrated circuits 1103 formed from a circuit cell and having an active gate in a gate in the circuit cell having a varied gate topography from a field gate in the gate for reduced gate layout parasitic capacitance, including, but not limited to, the integrated circuits 300, 300′ and gates 306, 306′, 306″ in FIGS. 3A, 5D-1 and 5D-2, 7E-1 and 7E-2, 8, and 9E, and according to any aspects disclosed herein. The wireless communications device 1100 may include or be provided in any of the above-referenced devices, as examples. As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals, e.g., I and Q output currents, for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency upconversion as well as noise in a receive frequency band. A power amplifier (PA) 1128 amplifies the upconverted signal 1124 from the filter 1126 to obtain the desired output power level and provides a transmitted RF signal. The transmitted RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Downconversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by amplifiers (AMPs) 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency upconversion, while the RX LO signal generator 1140 generates the I and Q RX LO signals used for frequency downconversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. An integrated circuit, comprising:
a diffusion region disposed above a substrate and having a longitudinal axis disposed in a first direction;
a non-diffusion region disposed above the substrate adjacent to the diffusion region;
a semiconductor channel disposed above the substrate in the diffusion region, the semiconductor channel having a longitudinal axis disposed in the first direction; and
a gate comprising a metal gate material, the gate having a longitudinal axis in a second direction substantially orthogonal to the first direction, the gate comprising:
an active gate region of the metal gate material disposed in the diffusion region in contact with the semiconductor channel to form an active gate; and
a field gate region of the metal gate material disposed in the non-diffusion region to form a field gate, wherein a height of a cross-section of at least a portion of the active gate is greater than a height of a cross-section of at least a portion of the field gate.

2. The integrated circuit of claim 1, wherein an area of the cross-section of at least a portion of the active gate is greater than an area of the cross-section of at least a portion of the field gate.

3. The integrated circuit of claim 2, wherein a ratio of the area of the cross-section of at least a portion of the active gate to the area of the cross-section of at least a portion of the field gate is at least 1.5.

4. The integrated circuit of claim 1, wherein a ratio of a height of the cross-section of at least a portion of the active gate to a height of the cross-section of at least a portion of the field gate is at least 1.5.

5. The integrated circuit of claim 1, wherein the field gate comprises a dielectric layer disposed adjacent the metal gate material.

6. The integrated circuit of claim 1, wherein the field gate comprises a work function metal layer disposed between a dielectric layer and the metal gate material.

7. The integrated circuit of claim 1, wherein the field gate does not comprise a work function metal material.

8. The integrated circuit of claim 1, wherein the field gate does not comprise a dielectric layer adjacent the metal gate material.

9. The integrated circuit of claim 1, wherein:
the diffusion region comprises:
a P-type diffusion region disposed above the substrate and having a longitudinal axis disposed in the first direction; and
an N-type diffusion region disposed above the substrate and having a longitudinal axis disposed in the first direction substantially parallel to the longitudinal axis of the P-type diffusion region; and
the non-diffusion region is further disposed between the P-type diffusion region and the N-type diffusion region.

10. The integrated circuit of claim 1, further comprising a planar transistor comprising:
the semiconductor channel disposed in the diffusion region above the substrate;
a source disposed in a well region on a first side of the semiconductor channel;
a drain disposed in the well region on a second side of the semiconductor channel opposite of the first side; and
a dielectric layer disposed above the semiconductor channel between the semiconductor channel and the active gate.

11. The integrated circuit of claim 1, further comprising a Fin Field-Effect Transistor (FET) (FinFET) comprising:
the semiconductor channel comprising at least one semiconductor Fin disposed in the diffusion region above the substrate, the at least one semiconductor Fin having a longitudinal axis disposed in the first direction;
the active gate disposed around at least a portion of the at least one semiconductor Fin;
a source disposed in a first region of the at least one semiconductor Fin not surrounded by the active gate adjacent to a first side of the active gate; and
a drain disposed in a second region of the at least one semiconductor Fin not surrounded by the active gate adjacent to a second side of the active gate opposite of the first side of the active gate.

12. The integrated circuit of claim 1, further comprising a gate-all-around (GAA) transistor comprising:
the active gate disposed around the semiconductor channel;
a source disposed in a first region of the semiconductor channel not surrounded by the active gate adjacent to a first side of the active gate; and
a drain disposed in a second region of the semiconductor channel not surrounded by the active gate adjacent to a second side of the active gate opposite of the first side of the active gate.

13. The integrated circuit of claim 1, further comprising a gate capping material disposed above the active gate and the field gate, the gate capping material having a substantially planar top surface.

14. The integrated circuit of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

15. A method of fabricating an integrated circuit, comprising:
forming a semiconductor channel in a diffusion region above a substrate, the semiconductor channel comprising one or more channel structures each comprising a semiconductor material;
forming a gate of a metal gate material having a substantially planar first top surface at a first height above the substrate, the gate comprising an active gate region of the metal gate material disposed adjacent to at least a portion of the semiconductor channel in the diffusion region, and a field gate region of the metal gate material disposed in a non-diffusion region adjacent to the diffusion region;
removing the metal gate material of a first depth below the first top surface to recess the metal gate material in the active gate region to a second top surface above the substrate to form a first opening in the active gate region, and removing the metal gate material of the first depth in the field gate region to the second top surface above the substrate to form a second opening in the field gate region;
applying a mask to protect the first opening and exposing the second opening in the field gate region; and
removing the metal gate material in the second opening in the field gate region to a second depth below the second top surface to form a third opening in the field gate region.

16. The method of claim 15, wherein forming the gate further comprises forming a dielectric layer surrounding the metal gate material, wherein the active gate region comprises the dielectric layer, the dielectric layer surrounding the metal gate material adjacent to at least a portion of the semiconductor channel in the diffusion region, and the field gate region comprises the dielectric layer, the dielectric layer surrounding the metal gate material disposed in the non-diffusion region.

17. The method of claim 15, further comprising, before forming the gate:
forming a dummy gate comprising a dummy gate material, a work function metal layer in contact with the dummy gate material, and a dielectric layer in contact with the work function metal layer above the substrate, the dummy gate comprising an active dummy gate disposed around at least a portion of the semiconductor channel in the diffusion region, and a field dummy gate disposed in the non-diffusion region adjacent to the diffusion region;
removing the dummy gate material in the active dummy gate;
removing the dummy gate material, the work function metal layer, and the dielectric layer in the field dummy gate; and
filling the active dummy gate and the field dummy gate with the metal gate material.

18. The method of claim 15, further comprising disposing a gate capping material above the metal gate material in the third opening in the field gate region and disposing the gate capping material above the metal gate material in the first opening in the active gate region.

19. A method of fabricating an integrated circuit, comprising:
forming a material layer stack above a diffusion region and an adjacent non-diffusion region, the material layer stack comprising:
a gate comprising a metal gate material of a first height above a substrate, at least a portion of the metal gate material disposed above the diffusion region forming an active gate;
a hard mask layer above the metal gate material;
a lithography material layer above the hard mask layer; and
a photoresist material layer above the lithography material layer;
removing at least a portion of the material layer stack above the diffusion region to form at least one opening in the material layer stack above the diffusion region down to the hard mask layer;
filling the at least one opening with a second hard mask layer;
removing at least a portion of the lithography material layer and the photoresist material layer above the non-diffusion region; and
removing at least a portion of the metal gate material above the non-diffusion region to form a field gate at a second height above the substrate less than the first height of the active gate above the substrate.

20. The method of claim 19, further comprising planarizing a top surface of the second hard mask layer to a top surface of the material layer stack.
